(19) United States
(12) Patent Application Publication
(10) Pub. No.: US 2025/0275188 A1
(43) Pub. Date: Aug. 28, 2025

(54) TAPERED CHANNEL FORKSHEET TRANSISTOR

(71) Applicant: INTERNATIONAL BUSINESS MACHINES CORPORATION, ARMONK, NY (US)

(72) Inventors: Ruilong Xie, Niskayuna, NY (US); Brent A. Anderson, Jericho, VT (US); Lawrence A. Clevenger, Saratoga Springs, NY (US); Albert M. Chu, Nashua, NH (US)

(21) Appl. No.: 18/589,861

(22) Filed: Feb. 28, 2024

(51) Int. Cl. H01L 29/786; H01L 29/06; H01L 29/423; H01L 29/66; H01L 29/775

(52) U.S. Cl. CPC H10D 30/6757; H10D 30/014; H10D 30/031; H10D 30/43; H10D 30/6735; H10D 62/121; H10D 64/017

(57) ABSTRACT

A forksheet transistor includes a tapered channel that has an interfacial surface that is directly connected to an isolation pillar. The tapered channel has a region in which its cross-sectional vertical dimension reduces in thickness toward its end surface that is in direct contact with the isolation pillar. The tapered channel may improve electrostatic control by the gate of the forksheet transistor over the tapered channel, which may improve the functionality and/or efficiency of the forksheet transistor.

### BACKGROUND

Semiconductor integrated circuit (IC) devices are increasingly scaled smaller and smaller in size. One type of a transistor that may be utilized by such scaled semiconductor IC devices is a forksheet transistor. A forksheet transistor typically includes channels and source and drain regions of different transistors that are separated by an isolation pillar. The isolation pillar enables a relatively closer transistor pitch, which shrinks the size of the semiconductor IC device.

### SUMMARY

In an embodiment of the disclosure, a forksheet transistor is presented. The forksheet transistor includes an isolation pillar. The forksheet transistor further includes a transistor that includes a source region in direct contact with the isolation pillar and a drain region in direct contact with the isolation pillar. The forksheet transistor further includes a channel that is in direct contact with the source region and that is in direct contact with the drain region. The channel includes a top surface, a bottom surface, and an isolation-interface surface that is in direct contact with the isolation pillar. A vertical dimension of the isolation-interface surface is smaller than a vertical dimension between the top surface and the bottom surface.

In an embodiment of the disclosure, another forksheet transistor is presented. The forksheet transistor includes an isolation pillar. The forksheet transistor further includes a channel comprising a main body region and an interfacial tapered region, the interfacial tapered region comprising an isolation-interface surface that is in direct contact with the isolation pillar, wherein a vertical dimension of the isolation-interface surface is smaller than a vertical dimension of the main body region.

In an embodiment of the disclosure, a semiconductor integrated circuit (IC) device fabrication method is presented. The method includes forming an isolation pillar opening within a nanosheet row that includes an alternating series of active nanosheets and sacrificial nanosheets. The method further includes tapering respective end surfaces of the active nanosheets that are exposed by the isolation pillar opening.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a forksheet transistor with tapered channels, according to one or more embodiments of the disclosure.

FIG. 2 depicts a cross-section view of a tapered channel directly connected to a sidewall of an isolation pillar, according to one or more embodiments of the disclosure.

FIG. 3 depicts a partial structure top-down view of an illustrative semiconductor IC device that includes a forksheet transistor with tapered channels, according to one or more embodiments of the disclosure.

FIG. 4 through FIG. 14 depict various fabrication structure cross-section views of an illustrative semiconductor IC device that includes a forksheet transistor with tapered channels, according to one or more embodiments of the disclosure.

FIG. 15 depicts a method of fabricating a semiconductor IC device that includes a forksheet transistor with tapered channels, according to one or more embodiments of the disclosure.

### DETAILED DESCRIPTION

The embodiments of the present disclosure relate to a forksheet transistor that includes a tapered channel that has an interfacial surface that is directly connected to an isolation pillar. The tapered channel has a region in which its cross-sectional vertical dimension reduces in thickness toward the interfacial surface that is in direct contact with the isolation pillar. This reduction in vertical dimension or tapering of the channel toward the isolation pillar may improve electrostatic control by the gate of the forksheet transistor over the tapered channel, which may improve the functionality and/or efficiency of the forksheet transistor.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, field programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 10:1 or greater.

As used herein, the terms “imperfectly selective”, “imperfect selectively”, or the like in reference to a material removal or etch process denotes that the rate of material removal for a first material is greater than the rate of removal of a second material of the structure to which the material removal process is by a ratio of less than 10:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

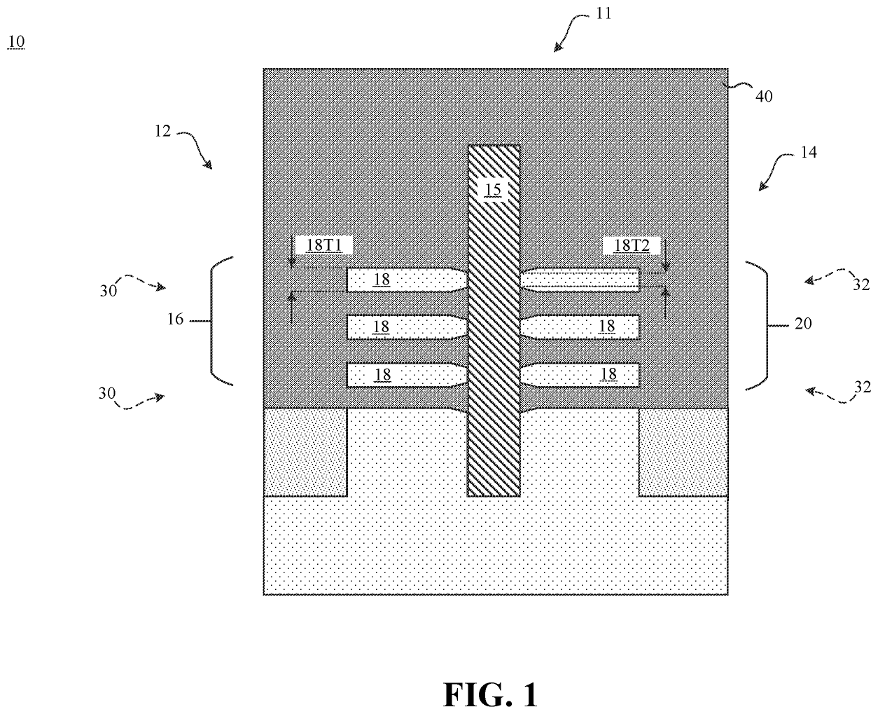

FIG. 1 depicts a cross-section view of a semiconductor IC device 10 that includes a forksheet transistor 11 with tapered channels 18, according to one or more embodiments of the disclosure. The forksheet transistor 11 may include a transistor 12 and a transistor 14 that are separated by an isolation pillar 15. A channel 16 of transistor 12, that may include one or more tapered channels 18, may be directly connected to the isolation pillar 15. Similarly, a channel 20 of transistor 14, that also may include one or more tapered channels 18, may be directly connected to the isolation pillar 15. For example, respective sidewall(s) of the tapered channels 18 of channel 16 may be directly connected to a first sidewall of the isolation pillar 15 and respective sidewall(s) of the tapered channels 18 of channel 20 may be directly connected to a second sidewall of the isolation pillar 15.

The transistor 12 may further include source/drain regions 30, located in different planes into and out of the page, that are directly connected to respective front and end surfaces of the tapered channels 18 of channel 16. Similarly, the transistor 12 may further include source/drain regions 32, located in different planes into and out of the page, that are directly connected to respective front and end surfaces of the tapered channels 18 of channel 20. In some implementations, the source/drain regions 30 are oppositely doped relative to the source/drain regions 32. For example, the source/drain regions 30 may be p-type source/drain regions and the source/drain regions 32 may be n-type source/drain regions. The isolation pillar 15 may extend into and out of the plane of the page and make direct contact with respective sidewalls of the source/drain regions 30 and the source/drain regions 32.

The transistor 12 and the transistor 14 may further include one or more gate(s) 40. The gate 40 controls whether the current path from the respective source/drain regions 30 and the source/drain regions 32 is an open circuit (“off”) or a resistive path (“on”). In the implementation depicted, the transistor 12 and the transistor 14 may share a single gate 40. In other implementations, the transistor 12 and the transistor 14 may utilize unique gates 40. In such implementations, for example, the isolation pillar 15 may extend above the top surface of the gates 40 and may adequately electrical separate or isolate the gates 40 from one another.

The tapered channel 18 has a vertical dimension 18T1 which is the respective distance between the top surface and bottom surface of the associated tapered channel 18. The tapered channel 18 also has an isolation-interface surface that is in direct contact with the isolation pillar 15. This isolation-interface surface has a respective vertical dimension 18T2 which is smaller than the vertical dimension 18T1 of the associated tapered channel 18. As such, each tapered channel 18 has a region in which its cross-sectional vertical dimension reduces in thickness toward its end that is in direct contact with the isolation pillar 15. The tapered nature of the tapered channel(s) 18 toward the isolation pillar 15 and the reduced dimension 18T2 of the isolation-interface surface may improve electrostatic control by the gate 40 over the tapered channel(s) 18, which may improve the functionality and/or efficiency of the forksheet transistor 11. For example, the taper may reduce the nanosheet thickness in the direction towards the isolation pillar 15, which may allow for improved electrostatic control by the gate 40 over the tapered channel(s) 18 near the isolation pillar 15.

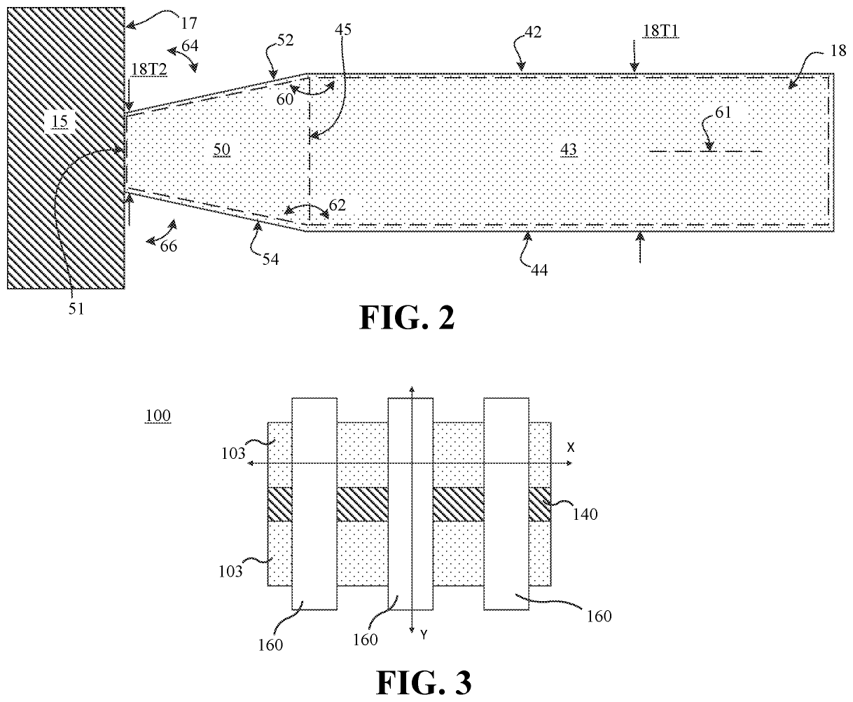

FIG. 2 depicts a cross-section view of the tapered channel 18 directly connected to a sidewall 17 of an isolation pillar 15, according to one or more embodiments of the disclosure. FIG. 2 more clearly depicts the top surface 42, the bottom surface 44, and the isolation-interface surface 51 of the tapered channel 18 and the isolation-interface surface 51 of the tapered channel 18 being in direct contact with the sidewall 17 of the isolation pillar 15.

In an example, the tapered channel 18 further includes a frontside facing surface 52 that connects the top surface 42 and the isolation-interface surface 51 and a backside facing surface 54 that connects the bottom surface 44 and the isolation-interface surface 51. Along with the isolation-interface surface 51, the frontside facing surface 52 and the backside facing surface 54 may define a taper of the tapered channel 18 in which the cross-sectional vertical dimension thereof reduces in thickness toward the isolation-interface surface 51. The taper may improve electrostatic control by the gate 40 over the tapered channel 18, which may improve the functionality and/or efficiency of the forksheet transistor 11.

In an example, the frontside facing surface 52 has an obtuse angle 60 with respect to the top surface 42 and the backside facing surface 54 has an obtuse angle 62 with respect to the bottom surface 44. The obtuse angle 60 and the obtuse angle 62 may be the same, substantially the same, or the like. The obtuse angle 60 and the obtuse angle 62 may be the result of the reduced dimension 18T2 compared to dimension 18T1 between the top surface 42 and the bottom surface 44.

In an example, the isolation-interface surface 51 is in direct contact with the sidewall 17 of the isolation pillar 15. Therefore, the tapered channel 18 may be arranged against the isolation pillar 15 to form a normally orientated forksheet transistor.

In an example, the frontside facing surface 52 has an acute angle 64 with respect to the sidewall 17 of the isolation pillar 15 and the backside facing surface 54 has an acute angle 66 with respect to the sidewall 17 of the isolation pillar 15. The acute angle 64 and the acute angle 66 may be the same, substantially the same, or the like. The acute angle 64 and the acute angle 66 may be the result of the reduced dimension 18T2 compared to dimension 18T1 between the top surface 42 and the bottom surface 44.

In an example, the frontside facing surface 52 is linear between the top surface 42 and the isolation-interface surface 51 and the backside facing surface 54 is linear between the bottom surface 44 and the isolation-interface surface 51. This shape may result from the material of the tapered channel 18 and the etch process utilized to fabricate the frontside facing surface 52 and the backside facing surface 54. For example, the material of the tapered channel 18 may be a crystalline semiconductor material and/or the etch process, utilized to remove portion(s) of the tapered channel 18, may form a (111) orientated crystallographic frontside facing surface 52 and a (111) orientated crystallographic backside facing surface 54.

In an example, the frontside facing surface 52 is nonlinear between the top surface 42 and the isolation-interface surface 51 and the backside facing surface 54 is nonlinear between the bottom surface 44 and the isolation-interface surface 51. Similarly, this shape may result from the material of the tapered channel 18 and the etch process utilized to fabricate the frontside facing surface 52 and the backside facing surface 54. For example, the material of the tapered channel 18 may be a graded or otherwise non-homogenous crystalline semiconductor material and/or the etch process, utilized to remove portion(s) of the tapered channel 18, may form arced or other non-liner frontside facing surface 52 and backside facing surface 54.

In an example, the tapered channel 18 has a horizontal bisector 61 which horizontally divides the tapered channel 18 into two equal parts. For example, frontside facing surface 52 and backside facing surface 54 may be mirrored relative thereto across horizontal bisector 61, top surface 42 and bottom surface 44 may be mirrored relative thereto across horizontal bisector 61.

In another embodiment, the forksheet transistor 11 includes the isolation pillar 15 and the tapered channel 18. The tapered channel 18 includes a main body region 43 and an interfacial tapered region 50. The interfacial tapered region 50 includes the isolation-interface surface 51 that is in direct contact with the isolation pillar 15. As before, the vertical dimension 18T2 of the isolation-interface surface 51 is smaller than the vertical dimension 18T1 of the main body region 43. The tapered nature of the tapered channel(s) 18 toward the isolation pillar 15 and the reduced dimension 18T2 of the isolation-interface surface 51 may improve electrostatic control by the gate that is or is to be associated with the tapered channel(s) 18, which may improve the functionality and/or efficiency of the forksheet transistor 11.

In an example, the interfacial tapered region 50 further includes the frontside facing surface 52 that connects the top surface 42 of the main body region 43 and the isolation-interface surface 51 and the backside facing surface 54 that connects the bottom surface 44 of the main body region 43 and the isolation-interface surface 51. Along with the isolation-interface surface 51, the frontside facing surface 52 and the backside facing surface 54 may define the interfacial tapered region 50 of the tapered channel 18 in which the cross-sectional vertical dimension thereof reduces in thickness toward the isolation-interface surface 51. The interfacial tapered region 50 may improve electrostatic control by the gate 40 over the tapered channel 18, which may improve the functionality and/or efficiency of the forksheet transistor 11. For example, the interfacial tapered region 50 may reduce the nanosheet thickness in the direction towards the isolation pillar 15, which may allow for improved electrostatic control by the gate 40 over the tapered channel(s) 18 near the isolation pillar 15.

FIG. 3 depicts a partial structural top-down view of a semiconductor IC device 100 that is to include one or more tapered channels (not shown) that are directly connected to an isolation pillar 140. The depicted view defines various cross-sectional planes that are utilized to depict the various fabrication cross-sectional views of semiconductor IC device 100. As depicted in the illustrated view, the semiconductor IC device 100 includes nanosheet rows 103 that are separated and connected to an isolation pillar 140 and one or more sacrificial gate structures 160. A cross-sectional plane “X” extends through one nanosheet row 103 and across sacrificial gate structure(s) 160. A cross-sectional plane “Y” extends through one sacrificial gate structure 160 and across the nanosheet rows 103 and isolation pillar 140.

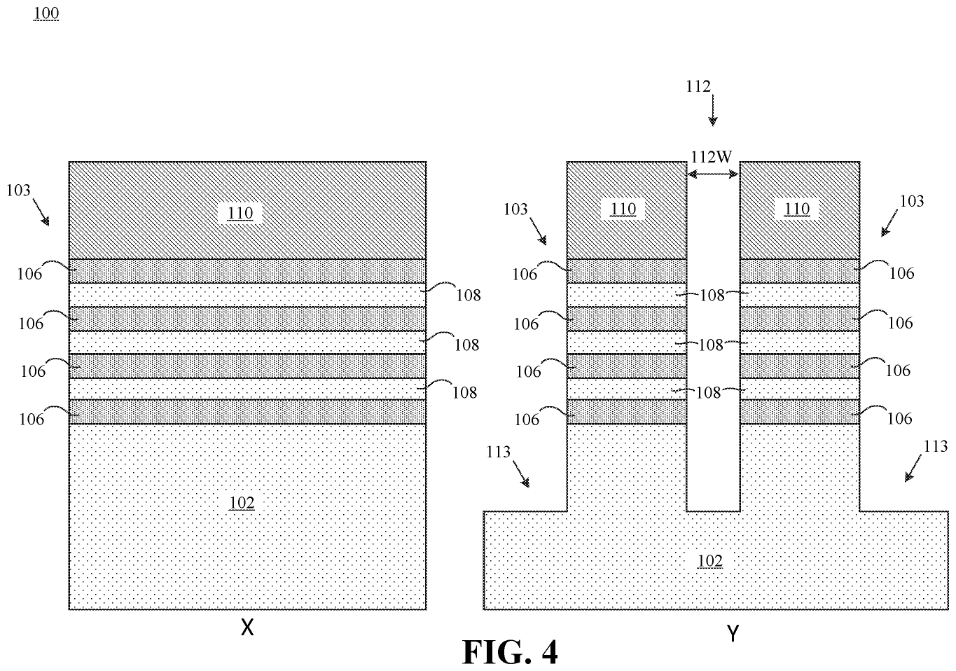

FIG. 4 depicts a cross-sectional initial fabrication view of the semiconductor IC device 100 that is include a forksheet transistor with tapered channels. At this initial fabrication stage, the semiconductor IC device 100 may include a substrate structure 102, nanosheet rows 103 which may include an alternating series of active nanolayers 108 and sacrificial nanolayers 106, a mask layer 110, and/or one or more isolation pillar openings 112.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. In another example, the substrate structure may include an upper substrate (not shown), a lower substrate (not shown), and an etch stop layer (not shown) between the upper substrate and the lower substrate. The upper substrate and the lower substrate may be comprised of any suitable material(s) including those listed above, and the etch stop layer may be a dielectric material with etch selectivity to one or both the upper substrate and/or the lower substrate. In one example, the etch stop layer may be an oxide and the substrate structure may be referred to as a buried oxide (BOX) substrate. In another example, the lower substrate may be composed of Si. The etch stop layer may be composed of Silicon Germanium (SiGe) and may be epitaxially grown from the top surface of lower substrate and the upper substrate may be composed of Si and may be epitaxially grown from the top surface of etch stop layer.

Next, the illustrative semiconductor IC device 100 may be formed by forming nanolayers over the substrate structure by forming a series of alternating sacrificial nanolayers 106 and active nanolayers 108, thereupon. In certain examples, the bottommost sacrificial nanolayer is initially formed directly on an upper surface of the substrate structure 102. In other examples, certain layer(s) may be formed between the upper surface of the substrate structure 102 and the bottommost sacrificial nanolayer 106.

The sacrificial nanolayers 106 can have Ge percentages ranging from 20% to 45%. In an implementation, the alternating active sacrificial nanolayer 106 and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the sacrificial nanolayers 106 and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers 108 to reduce the parasitic capacitance and to improve circuit speed. For example, the VSP (the distance between vertically adjacent active nanolayers 108) may range from 5 nm to 15 nm. However, the VSP must be of a sufficient value to accommodate the formation of a gate that is to be formed in the spaces created by later removal of respective portions of the sacrificial nanolayers.

Further, in the depicted fabrication stages, the nanolayers may be patterned into nanolayer rows 103. To form one or more nanolayer rows 103, a mask layer 110 may be formed on the uppermost nanolayer. The mask layer 110 may be comprised of any suitable mask material(s). The mask layer 110 may be patterned and used to perform the nanolayer row 103 patterning process. In the nanolayer row 103 patterning process, any suitable material removal process (e.g., reactive ion etching or RIE) may be used to remove portions of the alternating nanolayers down to the level of the substrate structure 102, or the like. Following the nanolayer stack patterning process, the one or more nanolayer rows 103 are formed. Subsequently, the mask layer 110 may be removed.

The removal of undesired portion(s) of the nanolayers may further remove undesired portions of substrate structure 102 that are adjacent to respective footprints of nanolayer rows 103 to form STI region openings 113. The etch may be timed or otherwise controlled to stop the removal of the substrate structure 102 such that the depth or bottom of the one or more STI region openings 113 has a predetermined or desired dimension. For example, the depth or bottom of the one or more STI region openings 113 may be above the etch stop layer.

As depicted, the nanolayer rows 103 patterning process may form one or more isolation pillar opening(s) 112 that between adjacent nanolayer rows 103. The isolation pillar opening(s) 112 dimension 112 W may be chosen so as to adequately electrically isolate the adjacent nanolayer rows 103 when a predetermined dielectric or isolation material with an predetermined dielectric constant is deposited therein. The depth of the isolation pillar opening(s) 112 may be controlled to be below the top surface of the substrate structure 102. For example, the etch utilized to form the isolation pillar opening(s) 112 may be controlled stop the removal of the substrate structure 102 such that the depth or bottom of the one or more isolation pillar opening(s) 112 has a predetermined or desired dimension. For example, the depth or bottom of the one or more isolation pillar opening(s) 112 may be above the etch stop layer. In a particular example, the well or bottom surfaces of the isolation pillar opening(s) 112 and the STI region opening(s) 113 may be substantially coplanar.

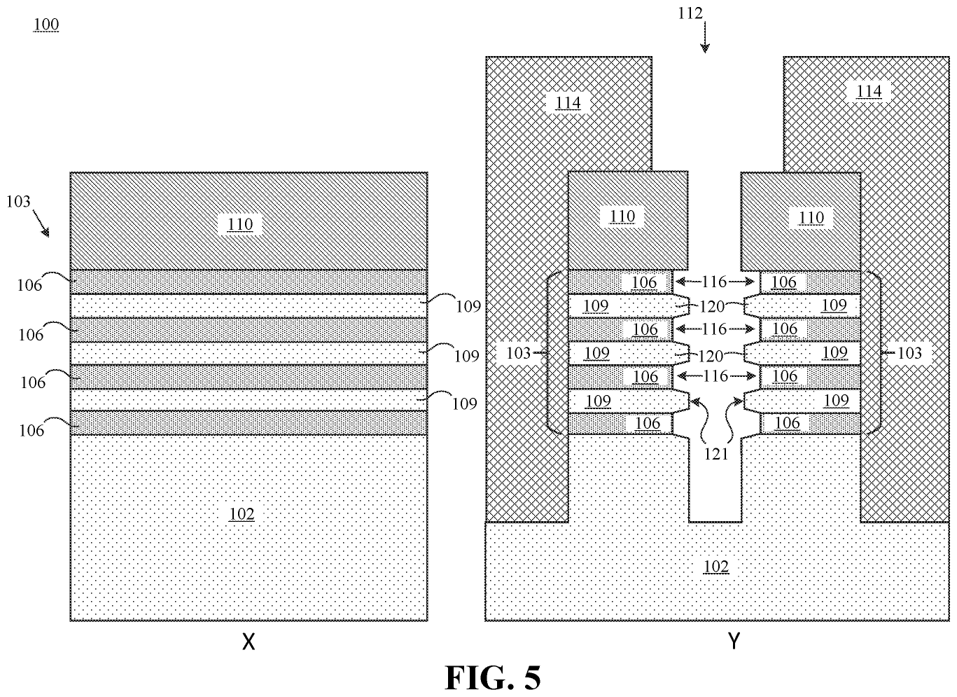

FIG. 5 depicts a fabrication structure cross-section view of illustrative semiconductor IC device 100 that is to include a forksheet transistor with tapered channels, according to one or more embodiments of the disclosure. In the depicted fabrication stage, from within the isolation pillar opening 112, tapered channels 109 are formed by forming a respective interfacial tapered region 120 within one or more active nanolayers 108.

The interfacial tapered region(s) 120 may be formed by forming a mask layer 114 upon the semiconductor IC device 100 and reopening (if necessary) the isolation pillar opening(s) 112 by removing a portion of the mask layer 114 associated therewith. The mask layer 114 may generally protect the portions of the semiconductor IC device 100 that shall not be subjected to the etch process or processes that are utilized to form the interfacial tapered region(s) 120. The mask layer 114 may consist of appropriate mask materials, such as those utilized as an organic planarization layer (OPL).

Next, the interfacial tapered region(s) 120 may be formed by forming horizontal or lateral indents 116 by laterally or horizontally removing respective portions of sacrificial nanolayers 106 within the nanolayer rows 103 that are exposed within the isolation pillar opening 112 with imperfect selectivity to the material of the active nanolayers 108.

The indents 116 and the interfacial tapered region(s) 120 may be simultaneously formed by an imperfectly selective reactive ion etch (RIE) process, which can remove portions of the sacrificial nanolayers 106 and respective corner portions of the active nanolayers 108 to form the interfacial tapered region(s) 120 and the resulting tapered channels 109. The horizontal depth of the indents 116 may be chosen to expose a predetermined portion of the active nanolayers 108 to define a horizontal dimension of the associated resulting interfacial tapered region(s) 120.

When the sacrificial nanolayers are composed of SiGe and when active nanolayers 108 are Si, the directional RIE can use a boron-based chemistry or a chlorine-based chemistry, for example, which recesses or removes the exposed end portions of sacrificial nanolayers (e.g., end portions of sacrificial nanolayers 106 exposed by the isolation pillar opening 112) with imperfect selectivity to the Si active nanolayers 108 so as to also simultaneously remove the corners of the active nanolayers 108 so as to resultantly form the respective interfacial tapered region 120 and the resulting tapered channels 109.

For clarity, the imperfect selectivity etch process to form interfacial tapered region 120 generally laterally removes relatively more material of the sacrificial nanolayers 106, relative to the material of the active nanolayers 108, within a predetermined etch exposure period of the same etch process. In a particular example, the relatively faster removal of the material of the sacrificial nanolayers 106 exposes the corners or edges of the active nanolayers 108 from within the isolation pillar opening 112. The imperfect selectivity etch process then more slowly removes the exposed corners or edges of the active nanolayers 108, resulting in the interfacial tapered region 120 of the active nanolayers 108.

For clarity, the tapered channels of the forksheet transistor may be structurally formed by the formation of the respective interfacial tapered region 120 in or otherwise associated with the active nanolayers 108 at the present fabrication. Therefore, the active nanolayers 108 may be subsequently referred to herein as tapered channels 109.

For further clarity, at the present fabrication stage, the tapered channels 109 may have an isolation-interface surface 121 that is exposed to the isolation pillar opening 112. The isolation-interface surface 121 may have a vertical dimension that is smaller than a vertical dimension between the top and bottom surfaces of the tapered channel 109, like the isolation-interface surface 51, the vertical dimension 18T2, and the vertical dimension 18T1 of the tapered channel 18 of FIG. 2. Similarly, the interfacial tapered region 120 may have an frontside facing surface and backside facing surface like the tapered channel 18 of FIG. 2. Similarity, the tapered channel 109 may have a main body region, top surface, bottom surface, or the like, like the tapered channel 18 of FIG. 2.

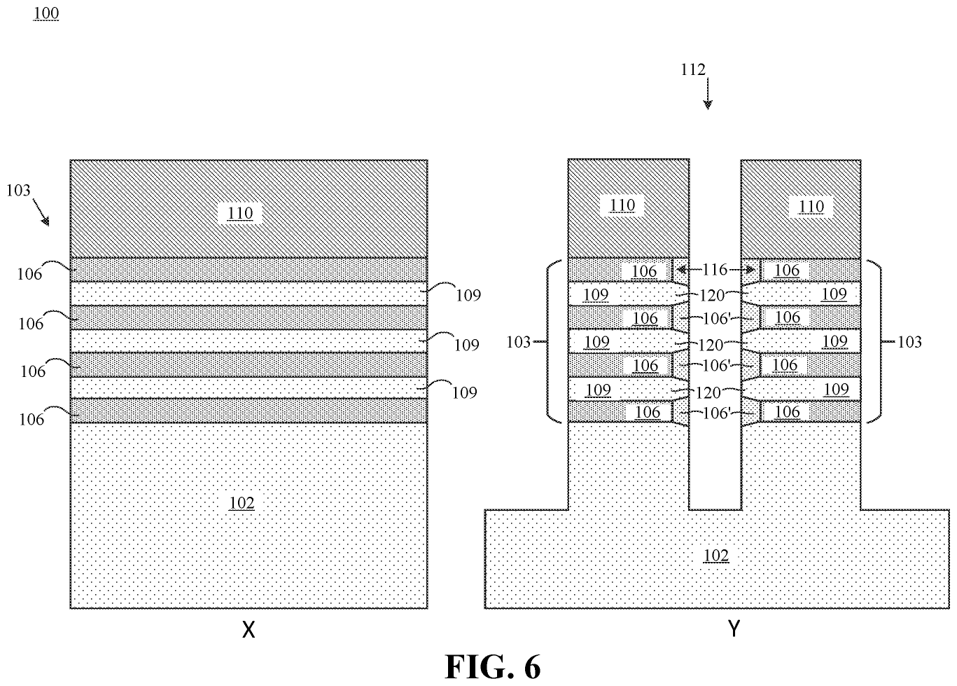

FIG. 6 depicts a fabrication structure cross-section view of illustrative semiconductor IC device 100 that is to include a forksheet transistor with tapered channels, according to one or more embodiments of the disclosure. In the depicted fabrication stage, from within the isolation pillar opening 112, a respective sacrificial inner spacer 106′ may be formed within each indent 116.

In one example, the sacrificial inner spacer 106′ can be formed by ALD or CVD or any other suitable deposition technique that deposits a same or similar material (e.g., a material without etch selectivity) as the sacrificial nanolayers 106 within the indents 116. In another example, the sacrificial inner spacer 106′ can be epitaxially grown from respective recessed sidewalls of the sacrificial nanolayers 106. In some examples, when the sacrificial nanolayers 106 are composed of SiGe, the sacrificial inner spacers 106′ may be composed of SiGe with substantially the same relative concentration of Ge as compared to the sacrificial nanolayers 106.

In certain implementations, after the formation of the sacrificial inner spacers 106′, a directional etch process is performed to create substantially vertical and/or coplanar sidewalls of the sacrificial inner spacers 106′ that are coplanar with the sidewalls of the tapered channels 109 and substrate structure 102 within the isolation pillar opening 112.

For clarity, the sacrificial inner spacers 106′ may be in direct contact with a respective or associated sacrificial nanolayer 106 and may be in direct contact with at least the interfacial tapered region 120 of a tapered channel 109 that is vertically above and/or below the sacrificial inner spacers 106′.

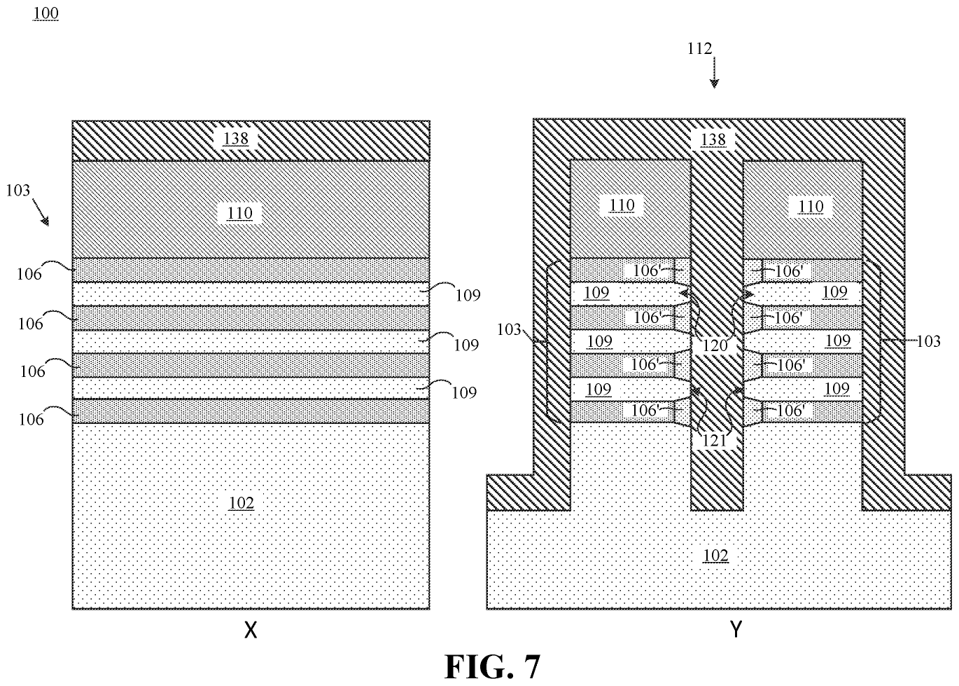

FIG. 7 depicts a fabrication structure cross-section view of illustrative semiconductor IC device 100 that is to include a forksheet transistor with tapered channels 109, according to one or more embodiments of the disclosure. In the depicted fabrication stage, isolation pillar layer 138 may be formed.

In an example, isolation pillar layer 138 may be formed to a thickness above the top surface of the mask layer 110. For clarity, within the isolation pillar opening 112, the isolation pillar layer 138 may be formed directly upon respective sidewalls of the sacrificial inner spacers 106′, directly upon respective sidewalls of the tapered channels 109 (i.e., directly upon the isolation-interface surface of each of the tapered channels 109), and directly upon the substrate structure 102.

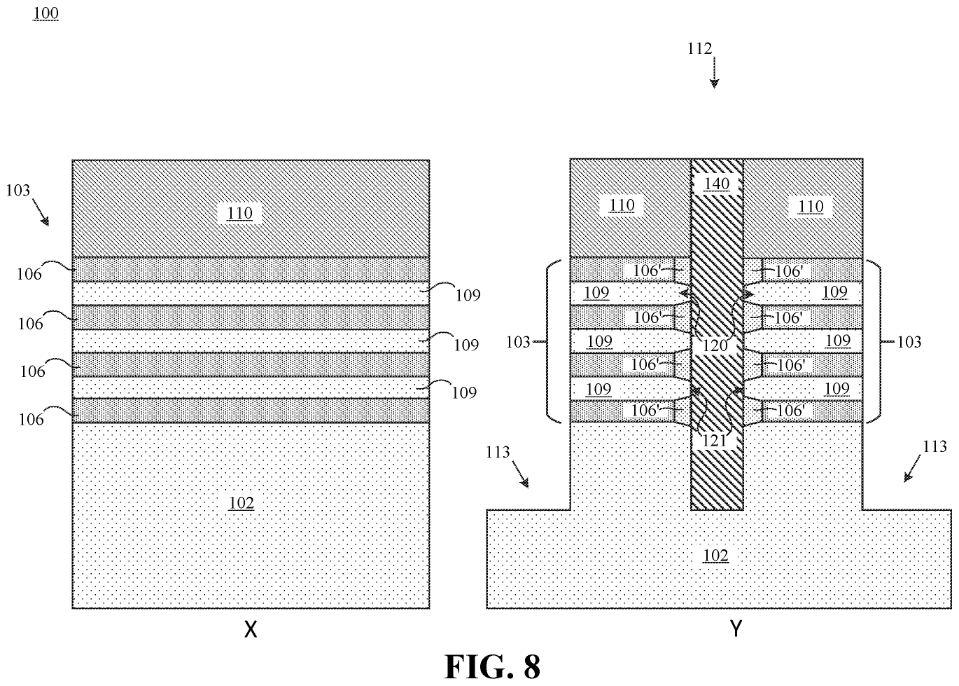

FIG. 8 depicts a fabrication structure cross-section view of illustrative semiconductor IC device 100 that is to include a forksheet transistor with tapered channels 109, according to one or more embodiments of the disclosure. In the depicted fabrication stage, isolation pillar 140 may be formed by removing excess portion(s) of isolation pillar layer 138, shown in FIG. 7.

Excess portion(s) of isolation pillar layer 138 may be removed by a substrative removal technique, such as an isotropic etch. The subtractive removal technique may generally remove the portion(s) of the isolation pillar layer 138 that are not pinched-off (e.g., located within respective isolation pillar opening(s) 112). For example, as depicted, the subtractive removal technique may remove the isolation pillar layer 138 on respective outer sidewall(s) of the nanosheet rows 103 (e.g., those sidewalls of the nanosheet rows 103 that face the STI region openings 113, etc.), may remove the isolation pillar layer 138 upon the substrate structure 102 within the STI openings 113, may remove the isolation pillar layer 138 upon respective outer sidewalls and upper surfaces of the mask layer 110, or the like. The isolation pillar layer 138 that remains within the isolation pillar opening 112 may generally form the isolation pillar 140.

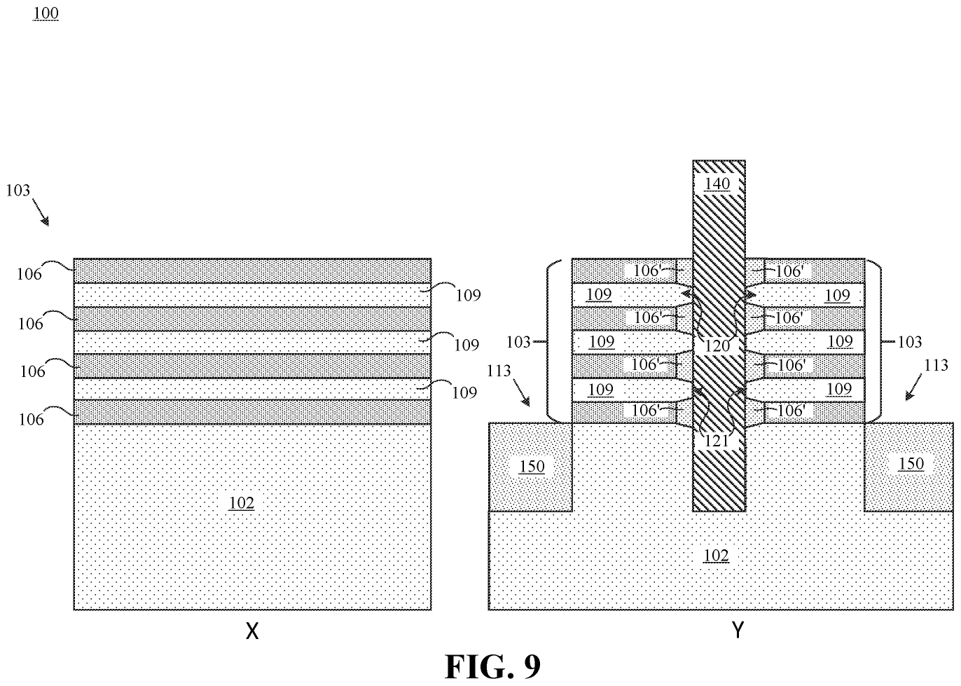

FIG. 9 depicts a fabrication structure cross-section view of illustrative semiconductor IC device 100 that is to include a forksheet transistor with tapered channels 109, according to one or more embodiments of the disclosure. In the depicted fabrication stage, STI regions 150 may be formed and mask layer 110 may be removed.

The mask layer 110 may be removed by a substrative removal technique, such as a wet etch. The removal of the mask layer 110 may expose an upper portion of the isolation pillar 140 that protrudes above the top surface of the topmost nanolayer within the nanosheet rows 103.

A STI region 150 may be formed upon and/or within the substrate structure 102 within a respective STI region opening 113. The STI region(s) 150 may be formed by depositing electrical dielectric material(s) adjacent to the one or more nanolayer rows 103 within STI region opening 113. A top surface of the one or more STI regions 150 may be substantially coplanar with or below a top surface of the substrate structure 102. In some implementations, further fabrication operations may generally remove portions of the STI regions 150 (e.g., sacrificial gate removal, replacement gate fabrication pre-clean, etc.), such that the top surface of the STI region 150 is below the top surface of the substrate structure 102.

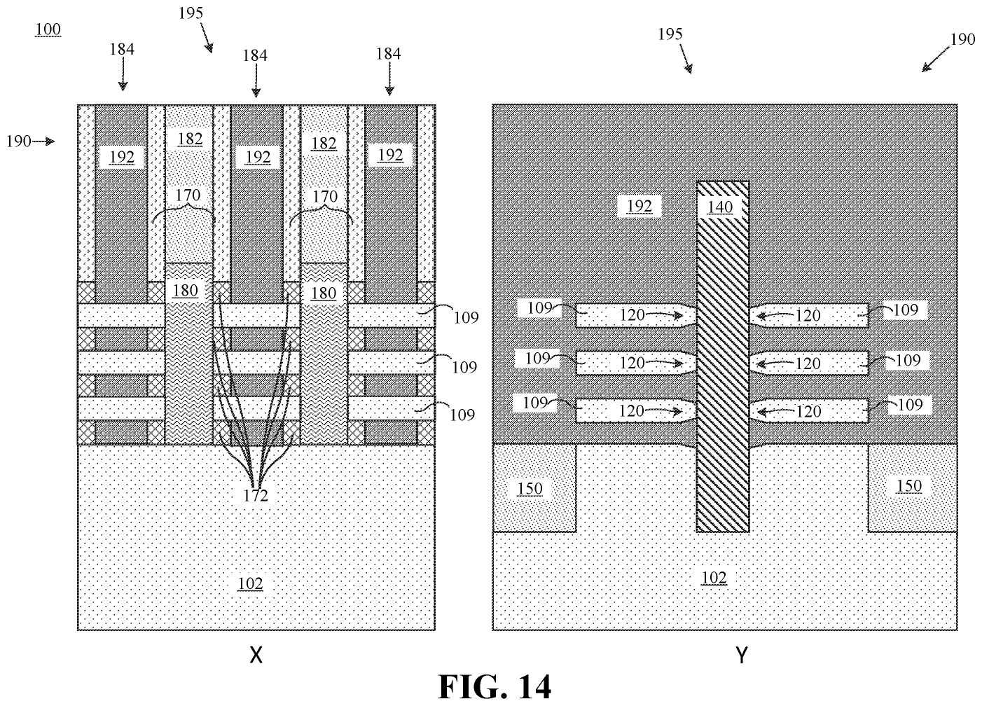

The one or more STI regions 150 may have a volume and/or geometry that sufficiently electrically isolates components or features of neighboring transistors. For example, a particular STI region 150 may separate and/or electrically isolate a particular nanosheet row (e.g., the depicted right nanosheet row 103) from an adjacent nanosheet row (now shown), a particular STI region 150 may separate and/or electrically isolate a particular forksheet transistor (e.g., forksheet transistor 195 depicted in FIG. 14) from an adjacent forksheet transistor (not shown).

In an example, the STI region 150 may be formed by depositing a STI liner within the STI region opening 113. Subsequently, the STI region 150 may be further formed by depositing STI dielectric material upon the STI liner. A etch back, recess, or the like, may occur to remove undesired or over formed STI liner and/or STI dielectric material, such that the top surface of the STI region 150 is substantially coplanar with or below a bottom surface of the bottommost sacrificial nanolayer 106. STI liner may be composed of but not limited to a nitride, low-K nitride (i.e., a nitride material with a lower dielectric constant relative to SiO₂), or the like. The STI dielectric material may be composed of but not limited to an oxide, low-K oxide (i.e., an oxide material with a lower dielectric constant relative to SiO₂), or the like.

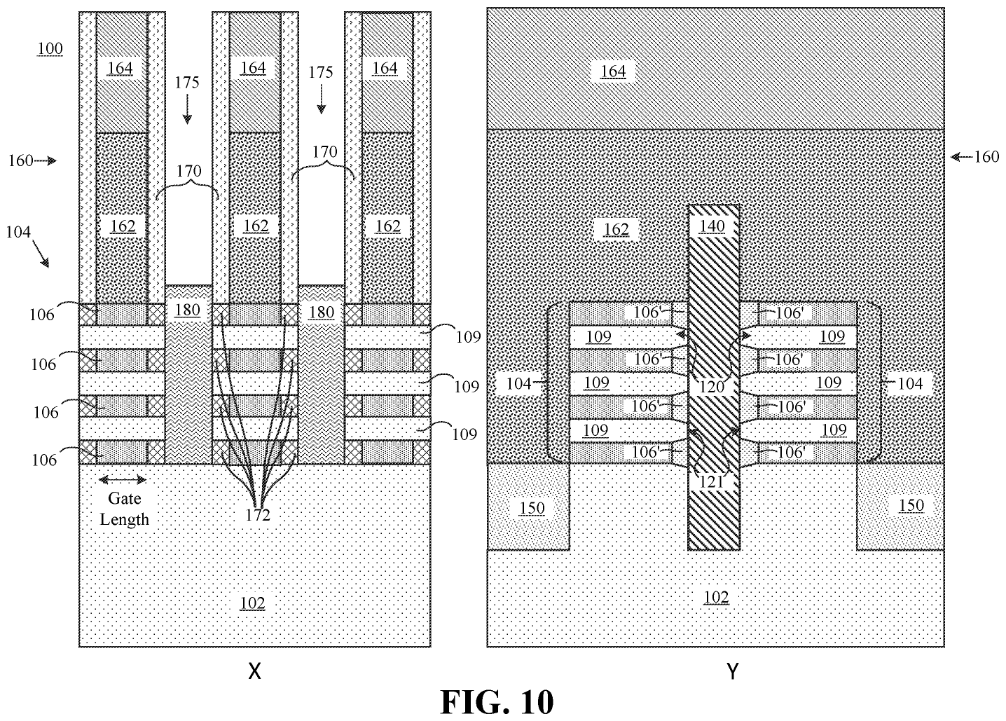

FIG. 10 depicts a fabrication structure cross-section view of illustrative semiconductor IC device 100 that is to include a forksheet transistor with tapered channels 109, according to one or more embodiments of the disclosure. In the depicted fabrication stage, sacrificial gate structures 160 may be formed, gate spacers 170 may be formed, S/D region opening(s) 175 may be formed, sacrificial nanolayers 106 and sacrificial inner spacers 106′ may be laterally indented, inner spacers 172 may be formed in the lateral indents, and respective source/drain (S/D) regions 180 may be formed.

The sacrificial gate structures 160 may include a sacrificial gate liner (not shown), a sacrificial gate 162, and a sacrificial gate cap 164. The sacrificial gate structures 160 may be formed by initially depositing a sacrificial gate liner layer (e.g., a dielectric, oxide, or the like) upon the one or more STI regions 150, upon and around the one or more nanolayer rows 103, and upon and around the exposed portion of the isolation pillar 140. The sacrificial gate structures 160 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the isolation pillar 140. The sacrificial gate structures 160 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 160 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 162, and the sacrificial gate cap 164, respectively, of each of the one or more sacrificial gate structures 160. The one or more sacrificial gate structures 160 can be formed on targeted regions or areas of semiconductor IC device 100 to define the gate length of one or more transistors and to provide sacrificial material for yielding targeted transistor structure(s).

The gate spacer(s) 170 may be formed by a conformal deposition of a dielectric material, such as silicon nitride, SiBCN, SiNC, SiN, SiCO, SiNOC, or a combination thereof, or the like, upon STI regions 150, upon around the one or more sacrificial gate structures 160, upon and around the one or more nanolayer rows 103, and upon and around the exposed portion of the isolation pillar(s) 140. Subsequently, undesired portions of dielectric material may be removed while desired portions the dielectric material may be retained and thereby form the gate spacers 170. The undesired portions of dielectric material may be removed by a directional ion etch, such as a reactive ion etch (RIE). The RIE may remove exposed or unprotected horizontal portions of the dielectric material while retaining protected vertical portions of the dielectric material to resultantly form the gate spacers 170.

The illustrated semiconductor IC device 100 may be further fabricated by forming S/D region opening(s) 175 within the one or more nanolayer rows 103 between gate spacers 170 of neighboring sacrificial gate structures 160. In other words, a single nanolayer row 103 may be separated, by one or more S/D region opening(s) 175, into multiple nanolayer stacks 104 with each nanolayer stack 104 located underneath a respective sacrificial gate structure 160 and associated gate spacer(s) 170.

The one or more S/D region opening(s) 175 may be formed by removing respective portions of the sacrificial nanolayers 106 and active nanolayers 108 that are between gate spacers 170 of adjacent or neighboring sacrificial gate structures 160. The one or more S/D region opening(s) 175 may be formed to a depth to stop at the top surface of the substrate structure 102, the top surface of STI regions 150, or the like.

The undesired portions of sacrificial nanolayers 106 and tapered channels 109 may be removed by etching or other subtractive removal techniques. The top surface of the substrate structure 102 and/or STI regions 150 may be used as an etch stop or other etch parameters may be controlled to stop the material removal at the substrate structure. As the gate spacers 170 and the sacrificial gate structures 160 may be utilized to protect the underlying portions of sacrificial nanolayers 106 and active nanolayers 108, respective sidewalls of the resulting nanolayer stacks 104 may be substantially coplanar and substantially vertical with the outer sidewalls of the gate spacers 170 there above.

As used herein, “substantially vertical” sidewalls deviate from a direction normal to a major surface (e.g., top surface, etc.) of the substrate structure 102 by less than 5°, e.g., 0°, 1°, 2°, 3°, 4°, or 5°, including ranges between any of the foregoing values.

The illustrated semiconductor IC device 100 may be further fabricated by forming horizontal or lateral indents within the sacrificial nanolayers 106 by laterally or horizontally removing respective portions of sacrificial nanolayers 106. The indents may be formed by a reactive ion etch (RIE) process, which can remove portions of the sacrificial nanolayers 106. The horizontal depth of the indents may be chosen to set a gate length for a replacement gate structure that is formed in place of one sacrificial gate structure 160. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers generally below gate spacer 170) selective to the tapered channels 109. In alternative implementations when sacrificial nanolayers are not SiGe and when active nanolayers 108 are not Si, the directional etch of the sacrificial nanolayers may generally be selective to the active nanolayers 108, gate spacers 170, STI regions 150, and/or substrate structure 102.

The illustrated semiconductor IC device 100 may be further fabricated by next forming a respective inner spacer 172 within each indent. The one or more inner spacers 172 can be formed by ALD or CVD or any other suitable deposition technique that deposits a dielectric material within the indent(s), thereby forming the inner spacers 172. In some examples, the inner spacers 172 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacers 172, a directional etch process is performed to create substantially vertical sidewalls of the inner spacers 172 that are coplanar with the substantially vertical sidewalls of the tapered channels 109 and/or of the gate spacers 170.

The illustrated semiconductor IC device 100 may be further fabricated by forming a respective S/D region 180 within a S/D region opening 175. For example, p-doped S/D regions 180 may be formed in a first formation sequence and n-doped S/D regions 180 may be formed in a second formation sequence, or vice versa.

Each S/D region 180 may form either a source or a drain, respectively, of a respective transistor and is connected to respective end surfaces of the active nanolayers 108. Each S/D region 180 is composed of a semiconductor material and a dopant. As used herein, a “source/drain” region can be a source region or a drain region depending on doping type and subsequent wiring and application of voltages during operation of the applicable transistor.

The semiconductor material that provides each of the S/D regions 180 may be composed of one of the semiconductor materials mentioned above for the substrate structure 102. For example, the semiconductor material that provides the S/D region 180 can be compositionally the same, or compositionally different from each active nanolayer 108. The dopant that is present in the S/D regions 180 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, include, but are not limited to, antimony, arsenic and phosphorous. When the semiconductor material is doped with a p-type dopant, the resulting S/D regions 180 may be referred to herein as being p-doped and when the semiconductor material is doped with a n-type dopant, the resulting S/D regions 180 may be referred to herein as being n-doped.

The S/D regions 180 may be epitaxially grown or formed. In some examples, the S/D regions 180 are formed by in-situ doped epitaxial growth. The use of an in-situ doping process is merely an example. For instance, one may instead employ an ex-situ process to introduce dopants into the S/D regions 180. Other doping techniques can be used to incorporate dopants in the S/D regions 180. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, S/D epitaxial growth conditions promote in-situ Boron doped SiGe for p-type transistor and phosphorus or arsenic doped silicon or Si:C for n-type transistors.

In some examples, the epitaxial growth that forms the S/D region 180 occurs or is promoted from the top surface of the substrate structure 102, or the like, while epitaxial growth may be limited or does not occur from neighboring STI regions 150.

In some implementations, epitaxial growth to form the one or more S/D regions 180 may overgrow above the upper surface of the sacrificial gate structure(s) 160 and be subsequently recessed such that the top surface of the S/D region(s) 180 may be substantially horizontal and above the top surface of the topmost tapered channel 109 (e.g., to enable contact between the end surface of that active nanolayer 108 and the S/D region 180). In other implementations, the epitaxial grown crystalline surfaces (e.g., (111) diamond crystalline surfaces) of the S/D region(s) 180 may be maintained.

For clarity, in a parallel plane to Y plane that exists into or out of the page, the S/D region 180 may be directly connected, grown directly against, or the like, to at least the associated end surfaces of the active nanolayers 108 and of the sacrificial nanolayers 106 and may be directly connected, grown directly against, or the like, to at least the associated side surface of the isolation pillar 140.

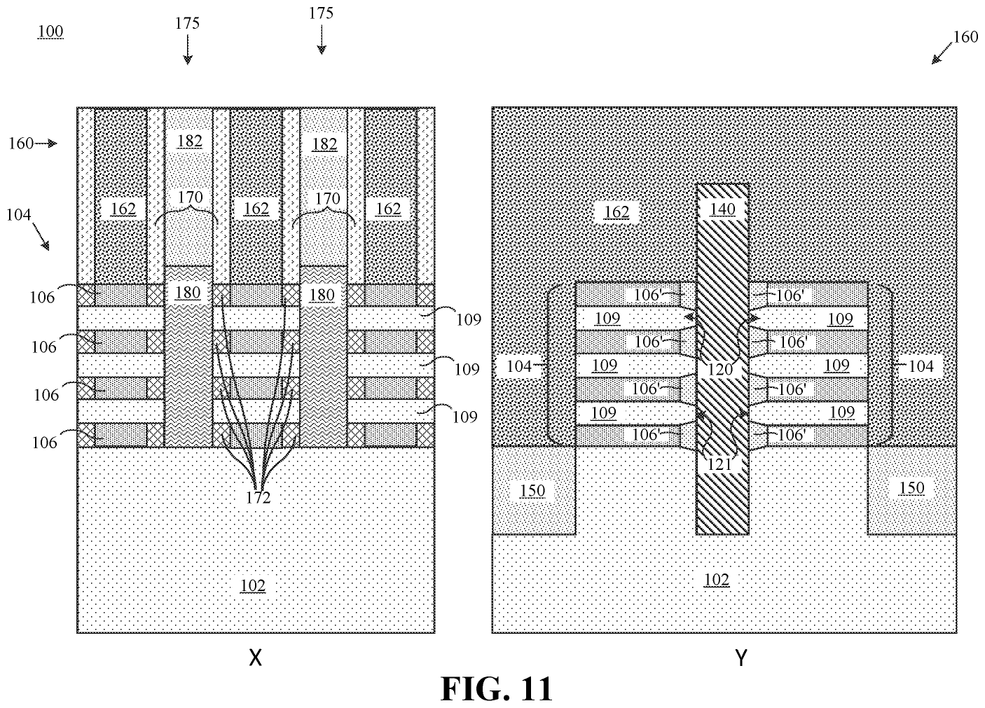

FIG. 11 depicts a fabrication structure cross-section view of illustrative semiconductor IC device 100 that is to include a forksheet transistor with tapered channels 109, according to one or more embodiments of the disclosure. In the depicted fabrication stage, interlayer dielectric (ILD) 182 may be formed. The ILD 182 may be formed by forming a blanket ILD over the S/D region(s) 180, over the STI region(s) 150, over the sacrificial gate structures 160, over the gate spacers 170, and over the isolation pillar 140, and/or the like.

The ILD 182 can be any suitable material, such as, for example, porous silicates, carbon doped oxides, silicon dioxides, silicon nitrides, silicon oxynitrides, OPL, or other dielectric materials. Any known manner of forming the ILD 182 can be utilized. The ILD 182 can be formed using, for example, CVD, PECVD, ALD, flowable CVD, spin-on dielectrics, or PVD.

In an example, the ILD 182 may be formed to a thickness above the top surface of the sacrificial gate structures 160. Subsequently, a planarization process, such as a CMP, may be performed to remove excess ILD 182 material and to remove the sacrificial gate caps 164 of the sacrificial gate structures, thereby exposing the sacrificial gate 162 thereunder. The planarization may also partially remove some of the sacrificial gates 162 or may at least expose the sacrificial gate 162 of the sacrificial gate structures 160. The CMP may create a substantially planar or substantially horizontal top surface for the semiconductor IC device 100. In other words, the respective top surfaces of ILD 182, gate spacers 170, sacrificial gate structures 160, S/D regions 180, etc. may be substantially coplanar and/or substantially horizontal.

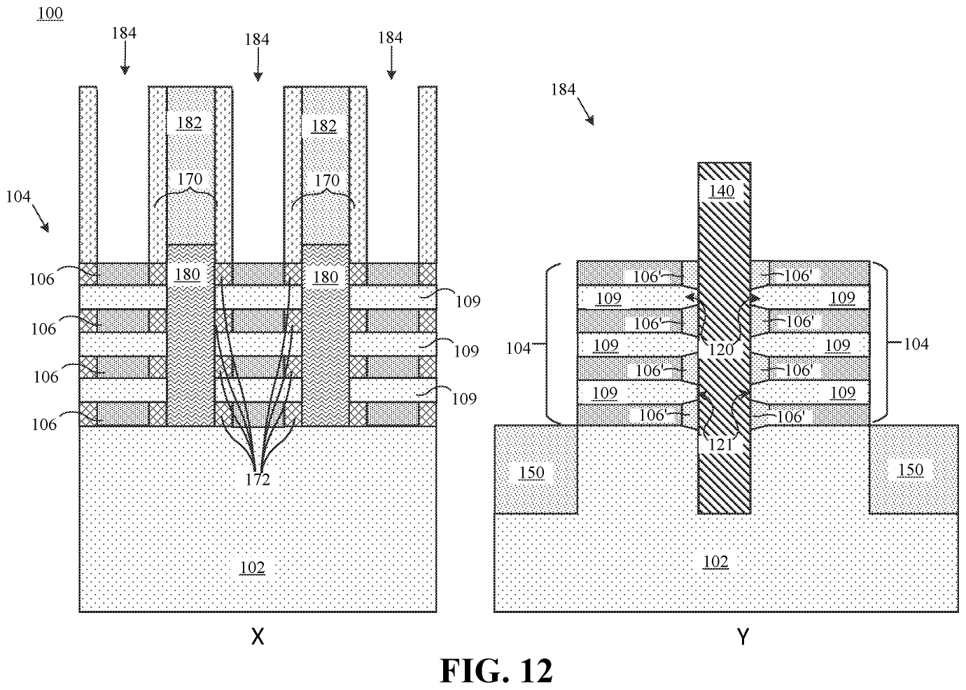

FIG. 12 depicts a fabrication structure cross-section view of illustrative semiconductor IC device 100 that is to include a forksheet transistor with tapered channels 109, according to one or more embodiments of the disclosure. In the depicted fabrication stage, respective replacement gate openings 184 may be formed by removing the remaining sacrificial gate structures 160.

The sacrificial gate structures 160 may be removed by removing the sacrificial gate 162 and sacrificial gate oxide by a removal technique, such as one or more series of etches. For example, such removal may be accomplished by a wet chemical etching process in which one or more chemical etchants are used to remove the sacrificial gate 162 and sacrificial gate oxide of the sacrificial gate structures 160. Appropriate etchants may be used that remove the sacrificial gate 162 and/or sacrificial gate oxide selective to the gate spacers 170, the tapered channels 109, the sacrificial nanolayers 106, the sacrificial inner spacer 106′, the STI regions 150, and the isolation pillar 140, or the like.

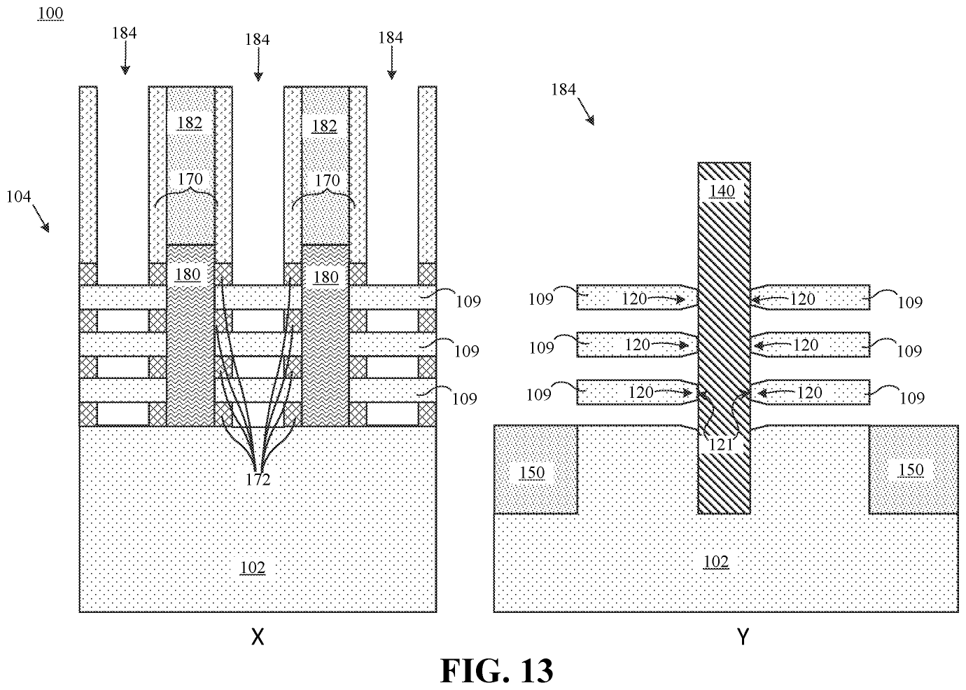

FIG. 13 depicts a fabrication structure cross-section view of illustrative semiconductor IC device 100 that is to include a forksheet transistor with tapered channels 109, according to one or more embodiments of the disclosure. In the depicted fabrication stage, the tapered channels 109 may be released by removing the sacrificial nanolayers 106 and the sacrificial inner spacer 106′ that are exposed within the respective replacement gate openings 184.

The active nanolayers 108 may be released by removing the sacrificial nanolayers 106 and the sacrificial inner spacers 106′ of the nanolayer stacks 104 within the respective replacement gate openings 184. The sacrificial nanolayers 106 and the sacrificial inner spacers 106′ may be simultaneously or sequentially removed by a removal technique, such as one or more series of etches. For example, the etching can include a wet chemical etching process in which one or more chemical etchants are used to remove the sacrificial nanolayers 106 and the sacrificial inner spacers 106′. Appropriate etchants may be used that remove the sacrificial nanolayers 106 and the sacrificial inner spacers 106′ selective to the active nanolayers 108, inner spacers 172, gate spacers 170, STI region(s) 150, isolation pillar 140, or the like. After the removal of sacrificial nanolayers 106 and the sacrificial inner spacers 106′ void spaces may be formed above and/or below the active nanolayers 108, which as a result, may effectively expose the respective interfacial tapered region 120 of each of the tapered channels 109.

FIG. 14 depicts a fabrication structure cross-section view of illustrative semiconductor IC device 100 that includes the forksheet transistor with tapered channels 109, according to one or more embodiments of the disclosure. In the depicted fabrication stage, respective one or more forksheet transistor(s) 195 may be formed upon the formation of respective replacement gate structure 190 within the respective replacement gate openings 184 around the isolation pillar 140 and around the tapered channels 109.

The replacement gate structure(s) 190 may be formed by initially forming an interfacial layer (not shown) on the gate spacers 170, on the tapered channels 109, on the inner spacers 172, on the substrate structure 102, on the STI region(s) 150, etc. that are interior to and/or upon the respective surfaces interior to the replacement gate openings 184 and the releasing of the tapered channels 109. The interfacial layer can be deposited by any suitable techniques, such as ALD, CVD, PVD, thermal oxidation, combinations thereof, or other suitable techniques.

The replacement gate structure(s) 190 may be further formed by forming a high-K layer (not shown) upon the exposed surfaces of the interfacial layer. The high-K layer can be deposited by any suitable techniques, such as ALD, CVD, metal-organic CVD (MOCVD), PVD, thermal oxidation, combinations thereof, or other suitable techniques. A high-K material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), or other suitable materials. The high-K layer can include a single layer or multiple layers, such as metal layer, liner layer, wetting layer, and adhesion layer. In other embodiments, the high-K layer can include, e.g., Ti, Ag, Al, TiAlN, TaC, TaCN, TaSiN, Mn, Zr, TiN, TaN, Ru, Mo, Al, WN, Cu, W, or any suitable materials.

The replacement gate structure(s) 190 may be further formed by depositing a work function (WF) gate (not shown) upon the high-K layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the forksheet transistor 195. The high-K layer may separate the WF gate from the tapered channels 109. Other metals that may be desired to further fine tune the effective work function (eWF) and/or to achieve a desired resistance value associated with current flow through the replacement gate structure 190 in the direction parallel to the plane of the tapered channels 109.

The replacement gate structure(s) 190 may be further formed by depositing a conductive gate 192. In an example, when none of the previous replacement gate material(s) are utilized in the replacement gate structures 190, the conductive gate 192 may be formed upon the same or similar surfaces as those upon which the interfacial layer, described above, may be formed. In other examples, when one or more of the interfacial layer, the high-K layer, the WF gate, or the like, are utilized in the replacement gate structures 190, the conductive gate 192 may be formed upon the most recent structural formation thereof.

The conductive gate 192 can be comprised of a conductor material and/or metal, such as but not limited to, e.g., tungsten, aluminum, ruthenium, rhodium, cobalt, copper, tantalum, titanium, carbon nanowire materials including graphene, or the like. The conductor material and/or metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 190 formation, the top surface of the semiconductor IC device 100 may be planarized by a planarization technique such as a CMP, mechanical grinding process, or the like. After the planarization technique, respective top surfaces of the ILD 182, gate spacers 170, replacement gate structures 190, or the like, may be substantially horizontal and/or may be substantially coplanar.

For clarity, in some implementations, a top surface of the replacement gate structure 190 may be coplanar with or below the top surface of the isolation pillar 140 to form two distinct gates. In other implementations, as depicted, a top surface of the replacement gate structure 190 may be above the top surface of the isolation pillar 140 to form a shared replacement gate structure 190 for both transistors of the forksheet transistor 195.

For clarity, the illustrated semiconductor IC device 100 may be fabricated with additional fabrication stages that are not depicted. For example, semiconductor IC device 100 may undergo middle of line (MOL) and back end of line (BEOL) fabrication stages. In the semiconductor IC device fabrication industry, there are three sections referred to in a build: front-end-of-line (FEOL), BEOL, and the section that connects those two together, the MOL. The FEOL is made up of the semiconductor devices, e.g., the forksheet transistor(s) 195, and the MOL is an interconnect between the FEOL and BEOL that includes material to prevent the diffusion of BEOL metals to FEOL devices.

BEOL is the second portion of IC fabrication where the individual devices (e.g., the forksheet transistor(s) 195) become interconnected with wiring on the semiconductor IC device, e.g., the metallization layer or layers of a wafer. The BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network may be formed on the frontside of the semiconductor device 100. Subsequently, a backside BEOL network may optionally be formed on the backside of the semiconductor IC device.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

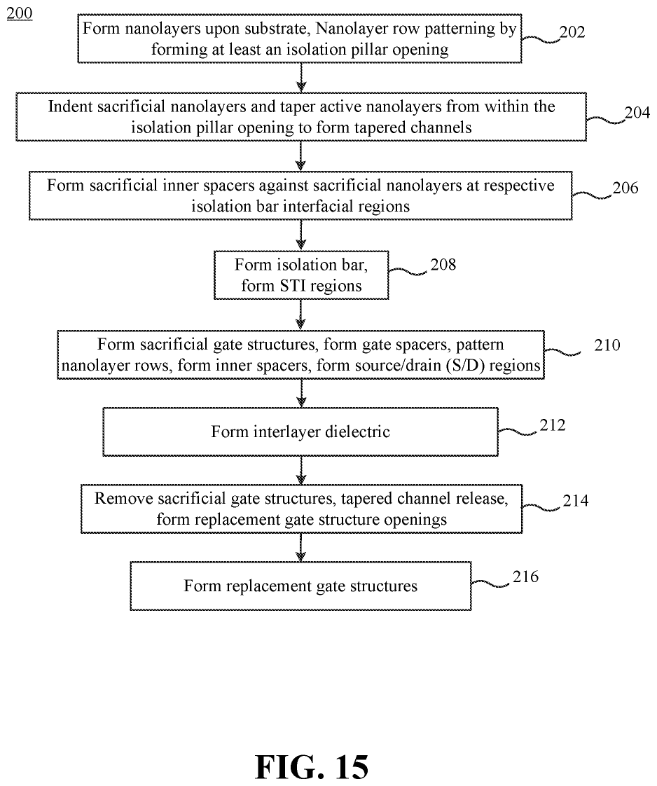

FIG. 15 depicts a flow diagram illustrating a method 200 to fabricate a semiconductor IC device, such as semiconductor IC device 100, though the fabrication operations described in method 300 may be used to fabricate other types of semiconductor IC devices. The depicted fabrication operations of method 200 may be illustratively depicted and described with reference to one or more of FIG. 4 through FIG. 14 of the drawings. The method 200 depicted herein is illustrative. There can be many variations to the diagram or operations described therein without departing from the spirit of the embodiments. For instance, the operations can be performed in a differing order, or operations can be added, deleted, or modified.

At block 202, method 200 may begin with forming nanolayers, such as sacrificial nanolayers 106 and active nanolayers 108, upon a substrate structure 102 and patterning the nanolayers into nanolayer rows 103 by the formation of isolation pillar opening(s) 112 and/or by the formation of STI region opening(s) 113.

At block 204, method 200 may continue with indenting the sacrificial nanolayers 106 while tapering the active nanolayers 108 within the isolation pillar opening(s) 112 to form tapered channels 109. For example, lateral indents 116 are formed within the sacrificial nanolayers 106 from within the isolation pillar opening(s) 112 with imperfect etch selectivity to the material of the active nanolayers 108, to both laterally indent the sacrificial nanolayers 106 and taper the active nanolayers 108.

At block 206, method 200 may continue with forming a respective sacrificial inner spacer 106′ within the lateral indent 116 against the sacrificial nanolayers 106 and against the interfacial tapered region 120 of the tapered channels 109 within the isolation pillar opening(s) 112.

At block 208, method 200 may continue with forming a respective isolation pillar 140 within each isolation pillar opening 112. Block 208 may further include forming an STI region 150 within each STI region opening 113.

At block 210, method 200 may continue with forming sacrificial gate structures 160, with forming gate spacers 170, with patterning the nanolayer rows 103 by forming S/D region openings 175 and nanolayer stacks 104, with laterally indenting the sacrificial nanolayers 106 from the S/D region openings 175, with forming a respective inner spacer 172 within each lateral indent, and with forming a respective S/D region 180 against the tapered channels 109 and against the isolation pillar 140.

At block 212, method 200 may continue with forming ILD 182. In certain implementations, block 212 may further include planarizing the semiconductor IC device to expose a portion (e.g., sacrificial gate 162) of the sacrificial gate structure 160.

At block 214, method 200 may continue with removing the sacrificial gate structures 160 and releasing the tapered channels 109 to form a replacement gate structure opening 184.

At block 216, method 200 may continue with forming a replacement gate structure 190 around the tapered channels 109, upon the isolation pillar 140, upon the STI regions 150, and the like, within a respective replacement gate opening 184.

For clarity, in an embodiment of the present disclosure, the method to fabricate the semiconductor IC device includes forming an isolation pillar opening 112 within a nanosheet row 103 that includes an alternating series of active nanolayers 108 and sacrificial nanolayers 106. The method further includes tapering respective end surfaces of the active nanolayers 108 that are exposed by the isolation pillar opening 112. The tapered channels 109 may improve electrostatic control by the to be formed replacement gate structure 190 over the tapered channels 109, which may improve the functionality and/or efficiency of the forksheet transistor 195. For example, the taper of the tapered channels 109 may reduce thereof in the direction towards the isolation pillar 140, which may allow for improved electrostatic control by replacement gate structure 190 over the tapered channels 109 near the isolation pillar 140.

In an example, the tapering of respective end surfaces of the active nanosheets exposed by the isolation pillar opening includes, from within the isolation pillar opening 112, laterally etching the sacrificial nanosheets 106 with imperfect selectivity to the active nanolayers 108. The formation of lateral indents 116 generally removes the material of the sacrificial nanosheets 106 at a faster rate than the material of the active nanolayers 108 and may resultant form the interfacial tapered region 120 thereof.

In an example, the method further includes forming a respective sacrificial inner spacer 106′ directly against the laterally etched sacrificial nanosheets 106 and against the interfacial tapered region 120. This reformation of the sacrificial nanosheets 106 allows for the isolation pillar 140, later formed within the isolation pillar opening 112, to have respective substantially vertical sidewalls with which the tapered channels 109 and S/D regions 180 may be in direct contact.

In an example, the method further includes forming isolation pillar 140 within the isolation pillar opening 112, wherein the respective tapered end surfaces of the tapered channels 109 (i.e., those surfaces of the tapered channels 109 that are exposed to the isolation pillar opening 112) are directly connected to a sidewall of the isolation pillar 140. Therefore, due to the taper of the tapered channels 109, there is relatively less channel surface area that is in direct contact with the isolation pillar 140.

In an example, the method further includes removing the laterally etched sacrificial nanosheets along with the respective sacrificial inner spacer that are associated therewith. In this manner, the tapered channels 109 are released so that the to be formed replacement gate structure 190 may be formed thereupon.

In an example, the method further includes forming a gate structure (i.e., replacement gate structure 190) directly against the isolation pillar 140 and directly against the tapered channels 109. Due to the taper of the tapered channels 109, there is relatively less channel surface area that is in direct contact with the isolation pillar 140.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A forksheet transistor comprising:
an isolation pillar;
a transistor comprising a source region in direct contact with the isolation pillar and a drain region in direct contact with the isolation pillar; and
a channel that is in direct contact with the source region and that is in direct contact with the drain region, the channel comprising a top surface, a bottom surface, and an isolation-interface surface that is in direct contact with the isolation pillar, wherein a vertical dimension of the isolation-interface surface is smaller than a vertical dimension between the top surface and the bottom surface.

2. The forksheet transistor of claim 1, wherein the channel further comprises:
a frontside facing surface that connects the top surface and the isolation-interface surface; and
a backside facing surface that connects the bottom surface and the isolation-interface surface.

3. The forksheet transistor of claim 2, wherein the frontside facing surface is obtusely angled with respect to the top surface and wherein the backside facing surface is obtusely angled with respect to the bottom surface.

4. The forksheet transistor of claim 3, wherein the isolation-interface surface is in direct contact with a sidewall of the isolation pillar.

5. The forksheet transistor of claim 4, wherein the frontside facing surface is acutely angled with respect to the sidewall of the isolation pillar and wherein the backside facing surface is acutely angled with respect to the sidewall of the isolation pillar.

6. The forksheet transistor of claim 5, wherein the frontside facing surface is linear between the top surface and the isolation-interface surface and wherein the backside facing surface is linear between the bottom surface and the isolation-interface surface.

7. The forksheet transistor of claim 5, wherein the frontside facing surface is nonlinear between the top surface and the isolation-interface surface and wherein the backside facing surface is nonlinear between the bottom surface and the isolation-interface surface.

8. A forksheet transistor comprising:
an isolation pillar; and
a channel comprising a main body region and an interfacial tapered region, the interfacial tapered region comprising an isolation-interface surface that is in direct contact with the isolation pillar, wherein a vertical dimension of the isolation-interface surface is smaller than a vertical dimension of the main body region.

9. The forksheet transistor of claim 8, wherein the interfacial tapered region further comprises:
a frontside facing surface that connects a top surface of the main body region and the isolation-interface surface; and
a backside facing surface that connects a bottom surface of the main body region and the isolation-interface surface.

10. The forksheet transistor of claim 9, wherein the frontside facing surface is obtusely angled with respect to the top surface of the main body region and wherein the backside facing surface is obtusely angled with respect to the bottom surface of the main body region.

11. The forksheet transistor of claim 10, wherein the isolation-interface surface is in direct contact with a sidewall of the isolation pillar.

12. The forksheet transistor of claim 11, wherein the frontside facing surface is acutely angled with respect to the sidewall of the isolation pillar and wherein the backside facing surface is acutely angled with respect to the sidewall of the isolation pillar.

13. The forksheet transistor of claim 12, wherein the frontside facing surface is linear between the top surface of the main body region and the isolation-interface surface and wherein the backside facing surface is linear between the bottom surface of the main body region and the isolation-interface surface.

14. The forksheet transistor of claim 12, wherein the frontside facing surface is nonlinear between the top surface of the main body region and the isolation-interface surface and wherein the backside facing surface is nonlinear between the bottom surface of the main body region and the isolation-interface surface.

15. A semiconductor integrated circuit (IC) device fabrication method comprising:
forming an isolation pillar opening within a nanosheet row that comprises an alternating series of active nanosheets and sacrificial nanosheets; and
tapering respective end surfaces of the active nanosheets that are exposed by the isolation pillar opening.

16. The semiconductor (IC) device fabrication method of claim 15, wherein tapering respective end surfaces of the active nanosheets exposed by the isolation pillar opening comprises:
from within the isolation pillar opening, laterally etching the sacrificial nanosheets with imperfect selectivity to the active nanosheets.

17. The semiconductor (IC) device fabrication method of claim 16, further comprising:
forming a respective sacrificial inner spacer directly against the laterally etched sacrificial nanosheets and against the respective tapered end surfaces of the active nanosheets.

18. The semiconductor (IC) device fabrication method of claim 17, further comprising:
forming an isolation pillar within the isolation pillar opening, wherein the respective tapered end surfaces of the active nanosheets are directly connected to a sidewall of the isolation pillar.

19. The semiconductor (IC) device fabrication method of claim 18, further comprising:
removing the laterally etched sacrificial nanosheets along with the respective sacrificial inner spacer that are associated therewith.

20. The semiconductor (IC) device fabrication method of claim 18, further comprising:
forming a gate structure directly against the isolation pillar and directly against the active nanosheets.
